(19) United States
(12) Patent Application Publication
(10) Pub. No.: US 2024/0039481 A1
(43) Pub. Date: Feb. 1, 2024

(54) AMPLIFIER

(71) Applicant: Sumitomo Electric Device Innovations, Inc., Yokohama-shi, Kanagawa (JP)

(72) Inventor: Seiji FUJITA, Yokohama-shi (JP)

(73) Assignee: Sumitomo Electric Device Innovations, Inc., Yokohama-shi, Kanagawa (JP)

(21) Appl. No.: 18/022,659

(22) PCT Filed: Oct. 5, 2021
(86) PCT No.: PCT/JP2021/036812

§ 371 Date: Feb. 22, 2023

(30) Foreign Application Priority Data
Oct. 6, 2020 (JP) 2020-169137

(51) Int. Cl. H03F 1/30; H03F 3/16

(52) U.S. Cl. CPC H03F 1/30; H03F 3/16; H03F 2200/447; H03F 2200/24

(57) ABSTRACT

An amplifier includes an amplifier circuit 10 having a characteristic changing in accordance with a thermal history, and a bias circuit 20 that includes an element subjected to a thermal history corresponding to the thermal history of the amplifier circuit, and supplies a bias voltage to the amplifier circuit. The bias voltage changes based on a characteristic of the element that changes in accordance with the thermal history of the element.

### TECHNICAL FIELD

The present disclosure relates to an amplifier. This application is based upon and claims the benefit of priority of Japanese Patent Application No. 2020-169137, filed on Oct. 6, 2020, the entire contents of which are incorporated herein by reference.

### BACKGROUND ART

A high-power and high-efficiency high-frequency amplifier uses a transistor such as a GaNFET (Field Effect Transistor) having an operating layer containing gallium nitride (GaN) or LDMOS (Laterally Diffused Metal Oxide Semiconductor). It is known that a bias circuit having a temperature compensation function is provided in order to compensate a temperature change of an idle current of an amplifying transistor (for example, PTL 1).

### CITATION LIST

### Patent Literature

PTL 1: Japanese Laid-open Patent Publication No. 2004-343244

### SUMMARY OF INVENTION

### Solution to Problem

An amplifier according to an aspect of the present disclosure includes an amplifier circuit having a characteristic changing in accordance with a thermal history; and a bias circuit that includes an element subjected to a thermal history corresponding to the thermal history of the amplifier circuit, and supplies a bias voltage to the amplifier circuit, the bias voltage changing based on a characteristic of the element that changes in accordance with the thermal history of the element; wherein the amplifier circuit includes a plurality of first transistors, each of the first transistors being a field effect transistor, the element includes a second transistor that is a field effect transistor, the first transistors and the second transistor are provided on a same semiconductor chip, and a characteristic changing in accordance with the thermal history of the amplifier circuit is a drain idle current of the first transistor.

### BRIEF DESCRIPTION OF DRAWINGS

FIG. 1 is a circuit diagram of an amplifier according to a first embodiment.

FIG. 2 is a cross-sectional view illustrating an example of the GaNFET used in the first embodiment.

FIG. 3 is a diagram illustrating a fluctuation amount of Idq in a high-temperature DC energization test.

FIG. 4 is a diagram illustrating a change amount ΔGL of a linear gain in the high-temperature DC energization test.

FIG. 5 is a circuit diagram of a bias circuit according to the first embodiment.

FIG. 6 is a diagram illustrating a change in characteristic of the transistor due to high-temperature DC energization.

FIG. 7 is a diagram illustrating a drain current IdABC with respect to a fluctuation amount ΔVg of a gate voltage.

FIG. 8 is a diagram illustrating a gate bias voltage VgPA with respect to the fluctuation amount ΔVg of the gate voltage.

FIG. 9 is a diagram illustrating a drain bias current IdPA with respect to the fluctuation ΔVg of the gate voltage.

FIG. 10 is a schematic plan view of the amplifier according to the first embodiment.

FIGS. 11A and 11B are plan views of the transistor according to the first embodiment.

FIGS. 12A to 12C are diagrams illustrating results of the high-temperature DC energization of a semiconductor device according to the first embodiment.

FIG. 13 is a schematic plan view of an amplifier according to a first variation of the first embodiment.

FIG. 14 is a schematic plan view of an amplifier according to a second variation of the first embodiment.

FIG. 15 is a Smith chart illustrating S22 of a first comparative example and the first and the second variations of the first embodiment.

FIG. 16 is a circuit diagram of a bias circuit according to a third variation of the first embodiment.

### DESCRIPTION OF EMBODIMENTS

### Technical Problem

Prolonged exposure of the amplifier to high temperature conditions (i.e., being subjected to a thermal history) may change the characteristic of the amplifier (e.g., a threshold voltage of the transistor). As a result, when the amplifier is operated for a long time, the temperature of the amplifier becomes high due to heat generation of the amplifier itself, and the characteristic changes.

It is an object of the present disclosure to suppress a change in characteristic of the amplifier caused by the thermal history.

### Effect of Present Disclosure

According to the present disclosure, it is possible to suppress a change in characteristic of the amplifier caused by the thermal history.

### DESCRIPTION OF EMBODIMENTS OF PRESENT DISCLOSURE

First, embodiments of the present disclosure will be listed and described.

(1) An aspect of the present disclosure is an amplifier including: an amplifier circuit having a characteristic changing in accordance with a thermal history; and a bias circuit that includes an element subjected to a thermal history corresponding to the thermal history of the amplifier circuit, and supplies a bias voltage to the amplifier circuit, the bias voltage changing based on a characteristic of the element that changes in accordance with the thermal history of the element; wherein the amplifier circuit includes a plurality of first transistors, each of the first transistors being a field effect transistor, the element includes a second transistor that is a field effect transistor, the first transistors and the second transistor are provided on a same semiconductor chip, and a characteristic changing in accordance with the thermal history of the amplifier circuit is a drain idle current of the first transistor. Thereby, it is possible to suppress a change in characteristic of the amplifier caused by the thermal history.
(2) The first transistor may amplify a high-frequency signal input to a gate and output the amplified high-frequency signal from a drain, and the bias circuit may supply a bias voltage to the gate of the first transistor.
(3) A source of the second transistor may be supplied with a first constant voltage, a drain of the second transistor may be connected to a node, the bias circuit may include a resistor having one end supplied with a second constant voltage and the other end connected to the node, and the bias voltage may be a voltage corresponding to a voltage of the node.
(4) A gate width of the second transistor may be smaller than a gate width of the first transistor, and a drain current per unit gate width of the second transistor may be larger than a drain current per unit gate width of the first transistor.
(5) A gate voltage of the second transistor may be larger than a gate bias voltage of the first transistor.
(6) The second transistor may be provided between the plurality of first transistors.
(7) A wiring of the bias circuit may intersect with a wiring through which signals input to the plurality of first transistors are transmitted and may not intersect with a wiring through which signals output from the plurality of first transistors are transmitted.
(8) The characteristic of the amplifier circuit may change irreversibly according to the thermal history.

### DETAILS OF EMBODIMENTS OF PRESENT DISCLOSURE

Specific examples of an amplifier according to an embodiment of the present disclosure will be described below with reference to the drawings. It should be noted that the present disclosure is not limited to these examples, and is defined by Claims, and is intended to embrace all the variations within the meaning and range of equivalency of the Claims.

### First Embodiment

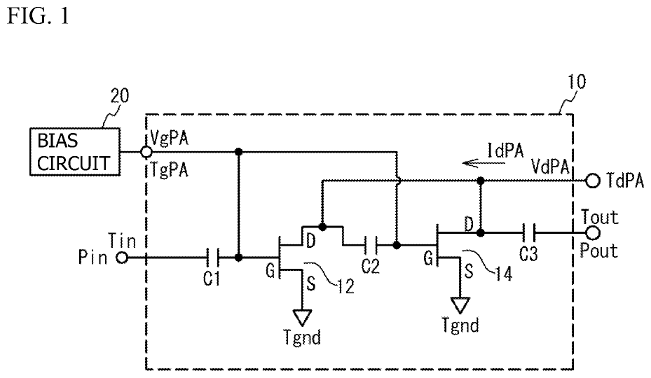

FIG. 1 is a circuit diagram of an amplifier according to the first embodiment. As illustrated in FIG. 1, the amplifier includes an amplifier circuit 10 and a bias circuit 20. The amplifier circuit 10 is a two-step amplifier circuit having transistors 12 and 14. The transistors 12 and 14 are field effect transistors (FET). A source S of the transistor 12 is connected to a ground terminal Tgnd. A gate G is connected to an input terminal Tin via a capacitor C1. A drain D is connected to a gate G of the transistor 14 via a capacitor C2. A source S of the transistor 14 is connected to the ground terminal Tgnd. A drain D is connected to an output terminal Tout via a capacitor C3.

The capacitors C1 to C3 are capacitors for cutting DC (Direct Current). The gates G of the transistors 12 and 14 are supplied with a gate bias voltage VgPA from a gate bias terminal TgPA. The drains D of the transistors 12 and 14 are supplied with a drain bias voltage VdPA from a drain bias terminal TdPA. A drain bias current IdPA flows through the transistors 12 and 14. A high-frequency signal having an input power Pin is input to the input terminal Tin. The high-frequency signal amplified by the transistors 12 and 14 is output from the output terminal Tout as a high-frequency signal having an output power Pout. The bias circuit 20 supplies the gate bias voltage VgPA to the gate bias terminals TgPA.

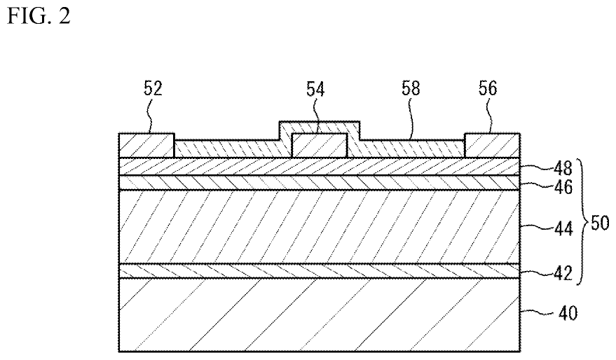

FIG. 2 is a cross-sectional view illustrating an example of the GaNFET used in the first embodiment. As illustrated in FIG. 2, a buffer layer 42, an electron transport layer 44, an electron supply layer 46 and a cap layer 48 are sequentially formed on a substrate 40 to form a nitride semiconductor layer 50. The substrate 40 is, for example, a SiC substrate, a sapphire substrate or a Si substrate. The buffer layer 42 is, for example, an AlN layer. The electron transport layer 44 is, for example, a GaN layer. The electron supply layer 46 is, for example, an AlGaN layer. The cap layer 48 is, for example, an n-type GaN layer. A gate electrode 54, a source electrode 52 and a drain electrode 56 are formed on the nitride semiconductor layer 50. The gate electrode 54 is disposed on the upper surface of the nitride semiconductor layer 50 between the source electrode 52 and the drain electrode 56. An insulating film 58 such as a silicon nitride film, a silicon oxide film or a silicon oxynitride film is formed on the nitride semiconductor layer 50 so as to cover the gate electrode 54. The nitride semiconductor layer 50 is not limited to each layer described above. For example, InGaN, AlInGaN, or InAlN may be used as the nitride semiconductor layer 50.

In the GaNFET using the nitride semiconductor layer 50, charge traps are formed between the substrate 40 and the nitride semiconductor layer 50 and/or between the nitride semiconductor layer 50 and the insulating film 58. When the FET is energized, the channel temperature of the FET increases. When the current is continued, the FET is exposed to the high temperature state for a long time. After such a thermal history, carriers are trapped in the traps and a threshold voltage changes. Even if the current is stopped and the FET is returned to room temperature, the threshold voltage does not return to an original level. When the threshold voltage changes, a drain idle current Idq also changes. Such a phenomenon is called high temperature Idq fluctuation. When a voltage is applied to the amplifier circuit 10 for a long period of time, the high-temperature Idq fluctuation occurs, and the drain idle current Idq irreversibly decreases. When the drain idle current Idq decreases, a gain decreases.

A description will be given of an example of the high-temperature Idq fluctuation of the GaNFET. The high-temperature DC (Direct Current) energization was performed on the amplifier circuit 10 of FIG. 1 using the GaNFET of FIG. 2. In the high-temperature DC energization, the gate bias voltage VgPA and the drain bias voltage VdPA are kept constant, and high-frequency power is not applied to the input terminal Tin. After the high-temperature DC energization for a predetermined period of time, the high-temperature DC energization was stopped, and a drain idle current and power characteristic were measured at room temperature. After that, the high-temperature DC energization was resumed.

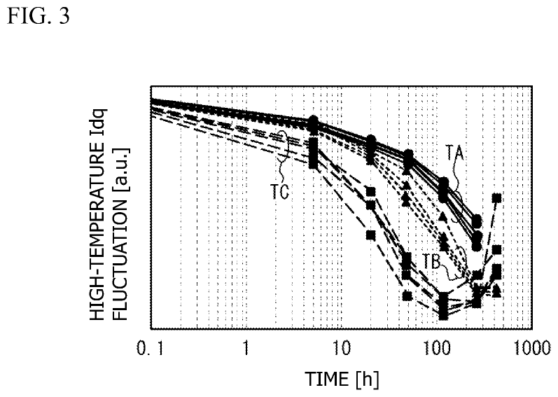

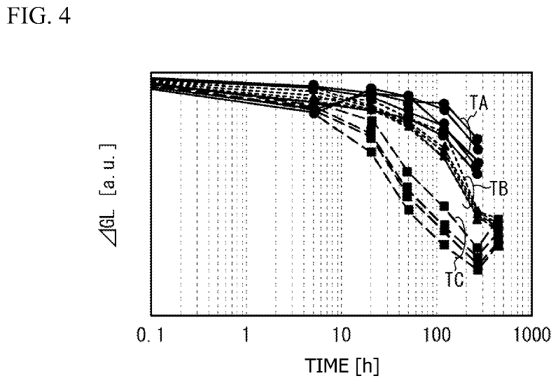

FIG. 3 is a diagram illustrating a fluctuation amount of Idq in a high-temperature DC energization test. FIG. 4 is a diagram illustrating a change amount ΔGL of a linear gain in the high-temperature DC energization test. In FIG. 4, a horizontal axis represents the time of the high-temperature DC energization, and a vertical axis represents the fluctuation amount of Idq in the high-temperature DC energization test from the drain idle current Idq before the high-temperature DC energization. In FIG. 3, the horizontal axis represents the time of the high-temperature DC energization, and the vertical axis represents the change amount ΔGL of GL from a linear gain GL before the high-temperature DC energization. The high temperature DC energization test was carried out at three channel temperatures TA, TB and TC. The temperature of TB is higher than that of TA, and that of TC is higher than that of TB. Dots are measured values, and straight lines are lines connecting the dots. Multiple samples were measured at the same temperature.

As illustrated in FIGS. 3 and 4, the drain idle current Idq and the linear gain GL decrease as the high-temperature DC energization time becomes longer. As the temperature is higher, the drain idle current Idq and the linear gain GL decrease greatly. At the temperature TC, the fluctuation of Idq is saturated in about 100 hours, and the decrease of the change amount ΔGL is saturated. As described above, when the high-temperature Idq fluctuation occurs, the power characteristic of the linear gain GL and the like of the amplifier circuit 10 changes, and the performance of the amplifier circuit 10 deteriorates.

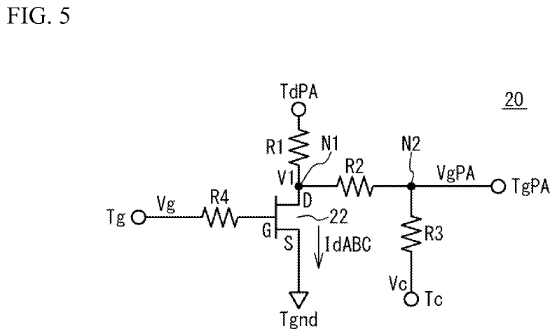

FIG. 5 is a circuit diagram of a bias circuit according to the first embodiment. As illustrated in FIG. 5, the bias circuit 20 includes a transistor 22. Similarly to the transistors 12 and 14 of the amplifier circuit 10, the transistor 22 is a transistor in which a fluctuation in threshold voltage occurs at a high temperature, and is the GaNFET of FIG. 2. A source S of the transistor 22 is connected to the ground terminal Tgnd. A gate G is connected to a gate terminal Tg via a resistor R4. A drain D is connected to a drain bias terminal TdPA via a resistor R1. A resistor R2 is connected between a gate bias terminal TgPA and a node N1 provided between the resistor R1 and the transistor 22. A resistor R3 is connected between a constant voltage terminal Tc and a node N2 provided between the resistor R2 and the gate bias terminal TgPA.

The drain bias terminal TdPA is supplied with the same drain bias voltage VdPA as the drain bias voltage VdPA of the amplifier circuit 10. A gate voltage Vg of a constant voltage is supplied to the gate terminal Tg. A constant voltage Vc is supplied to the constant voltage terminal Tc. The node N1 becomes a voltage V1 corresponding to a drain current IdABC of the transistor 22. When the drain current IdABC becomes low, the voltage V1 at the node N1 becomes high. A voltage obtained by dividing the voltage V1 and the constant voltage Vc by resistors R2 and R3 is output as the gate bias voltage VgPA to the gate bias terminal TgPA. Therefore, when the drain current IdABC decreases, the gate bias voltage VgPA increases.

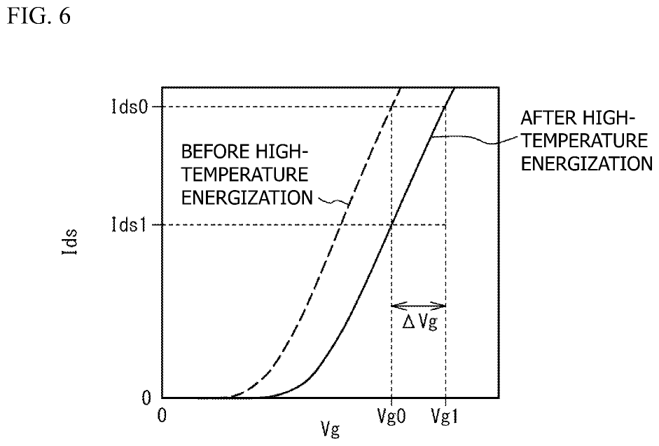

FIG. 6 is a diagram illustrating a change in characteristic of the transistor due to the high-temperature DC energization. A horizontal axis represents the gate voltage Vg of the transistor 22, and a vertical axis represents a drain current Ids. A drain voltage is 25V. A broken line illustrates a state before the high-temperature DC energization, and a solid line illustrates a state after the high-temperature DC energization. Before the high-temperature DC energization, when the gate voltage Vg is Vg0, the drain current Ids becomes Ids0. The high-temperature DC energization changes the threshold voltage of the transistor 22. Thus, when the gate voltage Vg is not changed from Vg0 even after the high-temperature DC energization, the drain current Ids decreases to Ids1. As described above, when the gate voltage Vg is not changed, the drain current Ids decreases after the high-temperature DC energization. In order to set the drain current Ids after high temperature energization to Ids0, the gate voltage Vg is set to Vg1. “Vg1-Vg0” corresponds to a fluctuation amount ΔVg of the gate voltage Vg. Thus, the drain current Ids of the transistor 22 decreases due to the high-temperature DC energization.

The transistor 22 is integrated on the same substrate as the amplifier circuit 10. When the transistors 12 and 14 are subjected to the thermal history due to the operation of the amplifier circuit 10 to cause the high-temperature Idq fluctuation, the transistor 22 of the bias circuit 20 also increases in temperature due to the energization and is subjected to the same thermal history. This causes the drain current IdABC of the transistor 22 to decrease as well as the high-temperature Idq fluctuations of the transistors 12 and 14.

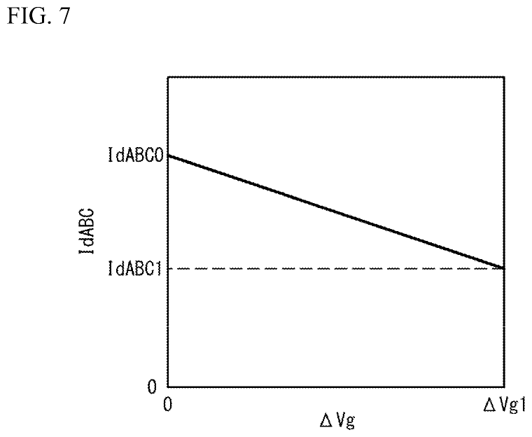

FIG. 7 is a diagram illustrating the drain current IdABC with respect to the fluctuation amount ΔVg of the gate voltage. As illustrated in FIG. 7, when the fluctuation amount ΔVg of the gate voltage is 0, the drain current IdABC is IdABC0. When the fluctuation amount ΔVg of the transistor 22 increases due to the thermal history, the drain current IdABC decreases. When the drain current IdABC decreases, the voltage V1 of the node N1 increases and the resistance values of the resistors R1 to R3 are set so that the gate bias voltage VgPA compensates for the decrease of the drain idle current Idq. When the fluctuation amount ΔVg of the gate voltage is A Vg1, the drain current IdABC is IdABC1.

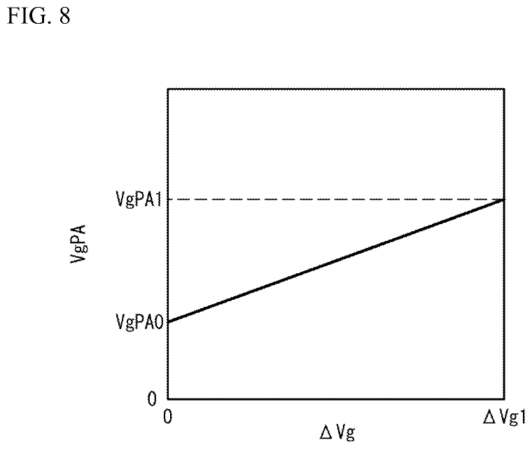

FIG. 8 is a diagram illustrating the gate bias voltage VgPA with respect to the fluctuation amount ΔVg of the gate voltage. As illustrated in FIG. 8, when the fluctuation amount ΔVg of the gate voltage is 0, the gate bias voltage VgPA is VgPA0. As the fluctuation amount ΔVg increases, the gate bias voltage VgPA increases. The gate bias voltage VgPA is set so as to compensate for the high-temperature Idq fluctuation of the transistors 12 and 14 due to the increase of the gate bias voltage VgPA. When the fluctuation amount ΔVg of the gate voltage is ΔVg1, the gate bias voltage VgPA is VgPA1.

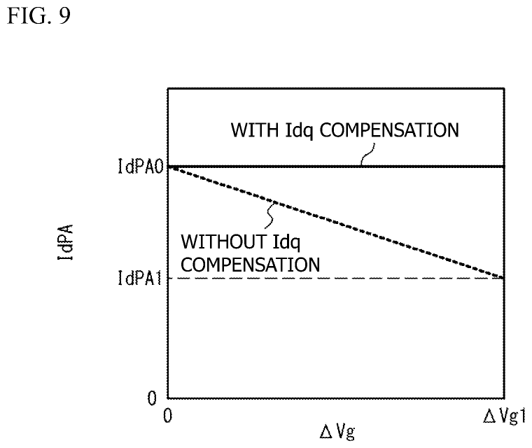

FIG. 9 is a diagram illustrating the drain bias current IdPA with respect to the fluctuation ΔVg of the gate voltage. A broken line represents a case where Idq is not compensated and the gate bias voltage VgPA is constant. A solid line represents a case where the bias circuit 20 increases the gate bias voltage VgPA so as to compensate for the fluctuation of Idq. As illustrated in FIG. 9, when the fluctuation amount ΔVg of the gate voltage is 0, the drain bias current IdPA is IdPA0 regardless of the presence or absence of Idq compensation. When the Idq compensation is not performed, the gate bias voltage VgPA is constant even if the fluctuation amount ΔVg varies in response to the fluctuation of Idq. Therefore, even if Idq varies, Idq is not compensated. When the fluctuation amount ΔVg of the gate voltage becomes ΔVg1, the drain bias current IdPA changes to IdPA1. When the Idq compensation is performed, the gate bias voltage VgPA becomes large as illustrated in FIG. 8 if the fluctuation amount ΔVg becomes large in response to the fluctuation of Idq. Therefore, the drain bias current IdPA is substantially constant, and the Idq fluctuation can be compensated. Even when the fluctuation amount ΔVg of the gate voltage becomes ΔVg1, the drain bias current IdPA is approximately IdPA0.

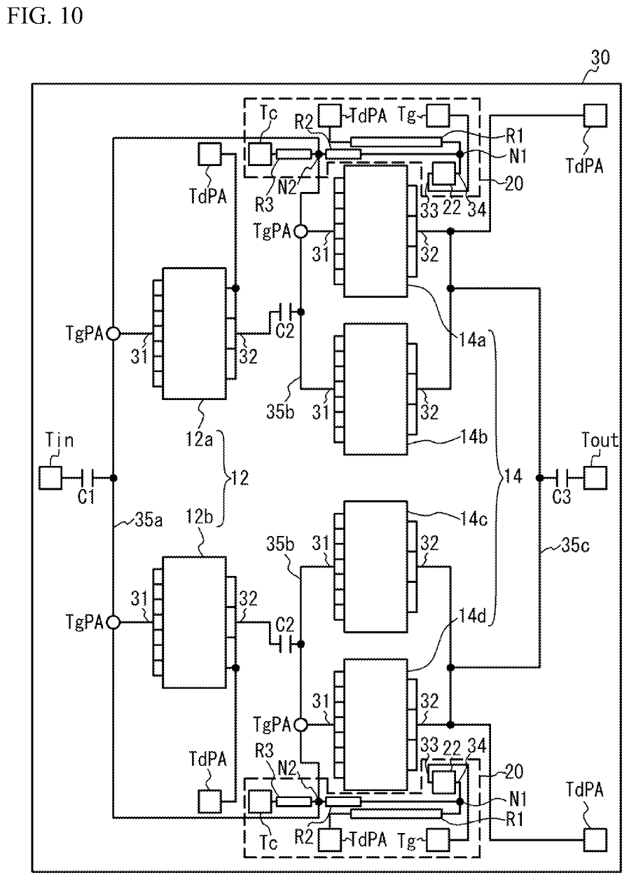

FIG. 10 is a schematic plan view of the amplifier according to the first embodiment. As illustrated in FIG. 10, the amplifier is formed as a monolithic microwave integrated circuit (MMIC) for amplifying a high-frequency signal of 17 GHz to 19 GHz. Transistors 12a, 12b and 14a to 14d, the input terminal Tin, the output terminal Tout, drain bias terminals TdPA, gate bias terminals TgPA, gate terminals Tg and constant voltage terminals Tc, capacitors C1 to C3, wirings 35a to 35c and the bias circuits 20 are provided on a semiconductor chip 30. The transistors 12a and 12b are connected in parallel between the input terminal Tin and the output terminal Tout to form the transistor 12. The transistors 14a to 14d are connected in parallel between the input terminal Tin and the output terminal Tout to form the transistor 14.

The input terminal Tin is electrically connected to gate wirings 31 of the transistors 12a and 12b by the wiring 35a. Drain wirings 32 of the transistors 12a and 12b and gate wiring 31 of the transistors 14a to 14d are electrically connected to each other by the wirings 35b. Drain wirings 32 of the transistors 14a to 14d and the output terminal Tout are electrically connected to each other by the wiring 35c. The gate bias terminals TgPA are connected to the wiring 35a. The capacitor C1 is provided between the input terminals Tin and the gate bias terminals TgPA in the wiring 35a. The drain bias terminals TdPA and the gate bias terminals TgPA are connected to the wirings 35b. The capacitors C2 are provided between the drain bias terminals TdPA and the gate bias terminals TgPA in the wirings 35b. The drain bias terminals TdPA are connected to the wiring 35c. The capacitor C3 is provided between the drain bias terminals TdPA and the output terminal Tout in the wiring 35c.

The bias circuits 20 are provided outside the transistors 14a and 14d. The transistors 22 are provided on the rear stages of the transistors 14a and 14d.

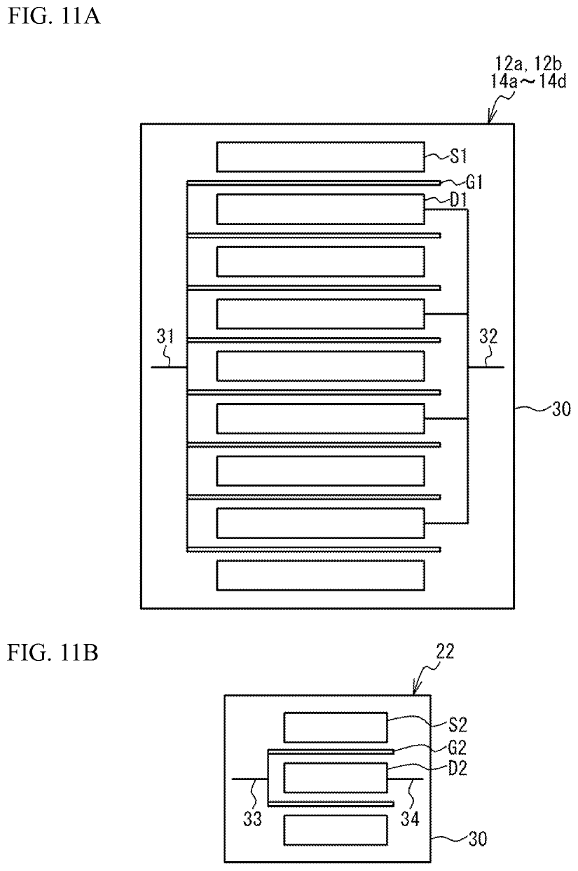

FIGS. 11A and 11B are plan views of the transistor according to the first embodiment. As illustrated in FIG. 11A, in the transistors 12a, 12b and 14a to 14d, a plurality of source electrodes S1 and a plurality of drain electrodes D1 are alternately arranged. Agate electrode G1 is provided between the source electrode S1 and the drain electrode D1. The source electrodes S1 are connected to the ground via through electrodes penetrating the semiconductor chip 30. The gate electrodes G1 are commonly connected to the gate wiring 31, and the drain electrodes D1 are commonly connected to the drain wiring 32.

As illustrated in FIG. 11B, in the transistor 22, a drain electrode D2 is provided between a pair of source electrodes S2. A gate electrode G2 is provided between the source electrode S2 and the drain electrode D2. The source electrodes S2 are connected to the ground via through electrodes penetrating the semiconductor chip 30. The gate electrodes G2 are commonly connected to a gate wiring 33, and the drain electrode D2 is commonly connected to a drain wiring 34.

With respect to the amplifiers illustrated in FIGS. 10, 11A and 11B, the high-temperature DC energization was performed with and without Idq fluctuation compensation in the bias circuit 20.
Transistors 12 and 14: GaNFET
Gate width of transistor 12: 400 μm
Gate width of transistor 14: 800 μm
Gate width of transistor 22: 80 μm
Resistance value of resistor R1: 50 Ω
Resistance value of resistor R2: 800 Ω
Resistance value of resistor R3: 70Ω
Drain bias voltage VdPA: 24 V
Gate voltage Vg: −1.84 V
Constant voltage Vc: −3.6 V
Temperature of lower surface of semiconductor chip 30: 85° C.

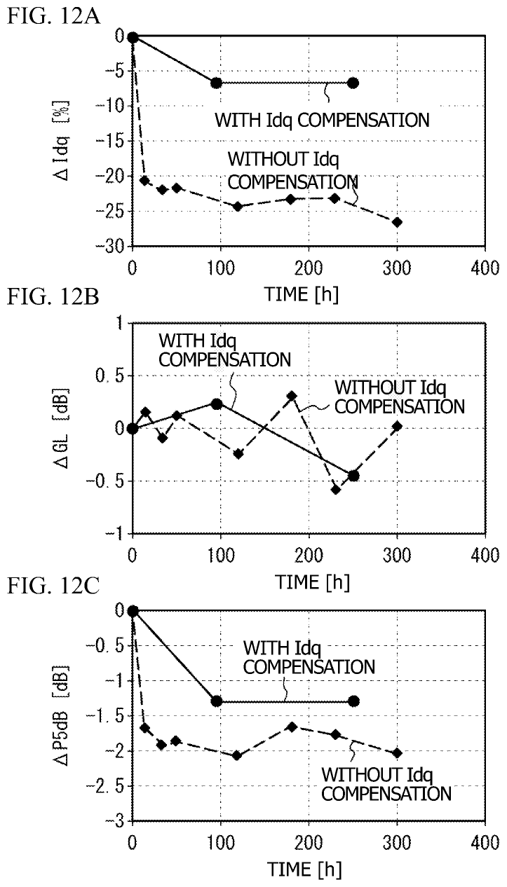

FIGS. 12A to 12C are diagrams illustrating results of the high-temperature DC energization of the semiconductor device according to the first embodiment. A horizontal axis represents the time of high-temperature DC energization. Vertical axes represent change amounts ΔIdq, ΔGL, and ΔP5 dB from the drain idle current Idq, the linear gain GL, and the linear gain P5 dB before the high-temperature DC energization. Here, P5 dB is a 5 dB gain compression point and an output power Pout which is lower than the straight line of the linear gain GL by 5 dB.

As illustrated in FIGS. 12A to 12C, when the Idq fluctuation compensation is not performed, the drain idle current Idq is reduced by 20% or more and the P5 dB is reduced by about 2 dB. When the Idq fluctuation compensation is performed, the drain idle current Idq is reduced by about 7% and the P5 dB is reduced by about 1.3 dB. Thus, by performing the Idq fluctuation compensation, a change in characteristic of the amplifier circuit caused by the high-temperature Idq fluctuation can be suppressed.

In the first embodiment, the amplifier in which the high-temperature Idq fluctuation occurs has been described, but when the characteristic of the amplifier circuit 10 changes in accordance with the thermal history, the bias circuit 20 may include an element subjected to a thermal history corresponding to the thermal history of the amplifier circuit 10, and may supply a bias voltage that changes based on the characteristic of the element that changes in accordance with the thermal history of the element to the amplifier circuit 10. As a result, a change in characteristic of the amplifier circuit 10 caused by the thermal history can be suppressed.

When the characteristic of the amplifier circuit 10 changes irreversibly according to the thermal history, it is particularly preferable to provide the bias circuit 20. Thus, an irreversible change in characteristic of the amplifier circuit 10 can be compensated.

The amplifier circuit 10 includes the transistors 12 and 14 (first transistors), and the bias circuit 20 includes the transistor 22 (second transistor) as an element. The transistors 12, 14 and 22 are provided on the same semiconductor chip 30. Thus, the characteristic of the transistor 22 changes in response to a change in characteristic due to the thermal history of the transistors 12 and 14. Therefore, the bias circuit 20 can change the bias voltage based on the thermal history of the transistors 12 and 14. From the viewpoint of reducing a chip area, the transistor 22 may be small. The gate width of the transistor 22 is preferably 1/10 or less of a total of the gate widths of the transistors 12 and 14.

The transistors 12 and 14 and the transistor 22 are FETs having an operating layer (the electron transport layer 44) containing gallium nitride. As a result, the high-temperature Idq fluctuation in which the drain idle current Idq changes occurs as the characteristic of the amplifier circuit 10. Therefore, it is preferable to compensate the Idq fluctuation by using the bias circuit 20.

The transistors 12 and 14 amplify the high-frequency signal input to the gate and output the amplified high-frequency signal from the drain. The bias circuit 20 changes the gate bias voltage VgPA of the transistors 12 and 14. Thus, the drain idle current Idq of the transistors 12 and 14 can be compensated.

As illustrated in FIG. 5, a ground potential (first constant voltage) is supplied to the source S of the transistor 22, and the drain of the transistor 22 is connected to the node N1. The bias circuit 20 includes the resistor R1 having one end supplied with the drain bias voltage VdPA (second constant voltage) and the other end connected to the node N1, and supplies a voltage corresponding to the voltage V1 of the node N1 as the gate bias voltage VgPA. Thus, when the drain current IdABC of the transistor 22 decreases, the gate bias voltage VgPA can be increased.

In a state before high-temperature energization in which the temperature of the lower surface of the semiconductor chip 30 is set to 85° C., the drain idle current Idq of the transistors 12 and 14 was set to 150 mA/mm, the drain current IdABC was changed by changing the gate voltage Vg of the transistor 22, and a channel temperature Tch@22 of the transistor 22 and a highest channel temperature Tch@14 among the transistors 14a to 14d were measured.

Table 1 represents the channel temperatures Tch@22 and Tch@14 with respect to the IdABC.

TABLE 1

| IdABC | Tch@22 | Tch@14 |
|---|---|---|
| [mA/mm] | [° C.] | [° C.] |
| 150 | 170 | 208 |
| 300 | 182 | 208 |
| 450 | 194 | 208 |
| 600 | 205 | 208 |

As illustrated in Table 1, assuming that the drain current IdABC of the transistor 22 is equal to the drain idle current Idq of the transistors 12 and 14, the channel temperature Tch@22 of the transistor 22 becomes lower than the channel temperature Tch@14 of the transistor 14 by 30° C. or more. Therefore, the thermal history of the transistor 22 becomes smaller than that of the transistor 14, and sufficient compensation for the Idq fluctuation may not be obtained.

Therefore, when the gate width of the transistor 22 is smaller than the gate width of the transistors 12 and 14, the drain current per unit gate width of the transistor 22 is made larger than the drain current per unit gate width of the transistors 12 and 14. For example, the gate voltage Vg of the transistor 22 is set larger than the gate bias voltage VgPA of the transistors 12 and 14. Thus, the channel temperature Tch@22 of the transistor 22 can be made substantially equal to the channel temperature Tch@14 of the transistor 14. For example, the drain current IdABC of the transistor 22 is set to 600 mA/mm. As a result, the channel temperature Tch@22 can be set within ±10° C. of Tch@14. Therefore, the Idq fluctuation can be sufficiently compensated. The gate width of the transistor 22 is, for example, ½ or less and preferably ⅕ or less of the gate width of the transistors 12 and 14. The drain current per unit gate width of the transistor 22 is, for example, 1.01 times or more and preferably 1.1 times or more the drain current per unit gate width of the transistors 12 and 14. The gate voltage Vg of the transistor 22 is larger than, for example, the gate bias voltage VgPA of the transistors 12 and 14 by 0.01 V or more and preferably by 0.1 V or more.

### First Variation of First Embodiment

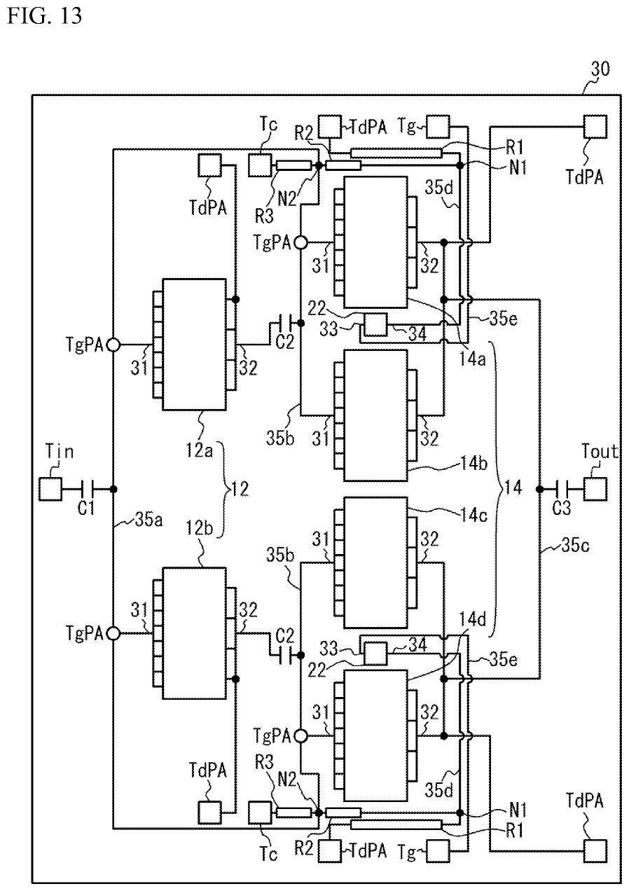

FIG. 13 is a schematic plan view of an amplifier according to a first variation of the first embodiment. As illustrated in FIG. 13, the transistors 22 are provided between the transistors 14a and 14b and between the transistors 14c and 14d. Wirings 35d connect the drain wirings 34 of the transistors 22 to the nodes N1, and the wirings 35e connect the gate wirings 33 of the transistors 22 to the gate terminals Tg. The wirings 35d and 35e intersect with the wiring 35c. Other configurations are the same as those of the first embodiment, and description thereof is omitted.

Table 2 represents the channel temperatures Tch@22 and Tch@14 with respect to the IdABC.

TABLE 2

| IdABC | Tch@22 | Tch@14 |
|---|---|---|
| (mA/mm) | [° C.] | [° C.] |
| 150 | 178 | 208 |
| 300 | 190 | 208 |
| 450 | 200 | 208 |

As illustrated in Table 2, in the first variation of the first embodiment, the channel temperature Tch@22 is higher than that in the first embodiment even in the same IdABC as the first embodiment. For example, when the IdABC is 150 mA/mm, the channel temperature Tch@22 is 170° C. in the first embodiment, and the channel temperature Tch@22 is 178° C. in the first variation of the first embodiment. In the first variation of the first embodiment, by setting the IdABC to 450 mA/mm, the channel temperature Tch@22 can be set within ±10° C. of Tch@14.

According to the first variation of the first embodiment, the plurality of transistors 14 are provided, and the transistors 22 are provided between the plurality of transistors 14a to 14d. Thus, the power consumption of the bias circuit 20 can be suppressed.

### Second Variation of First Embodiment

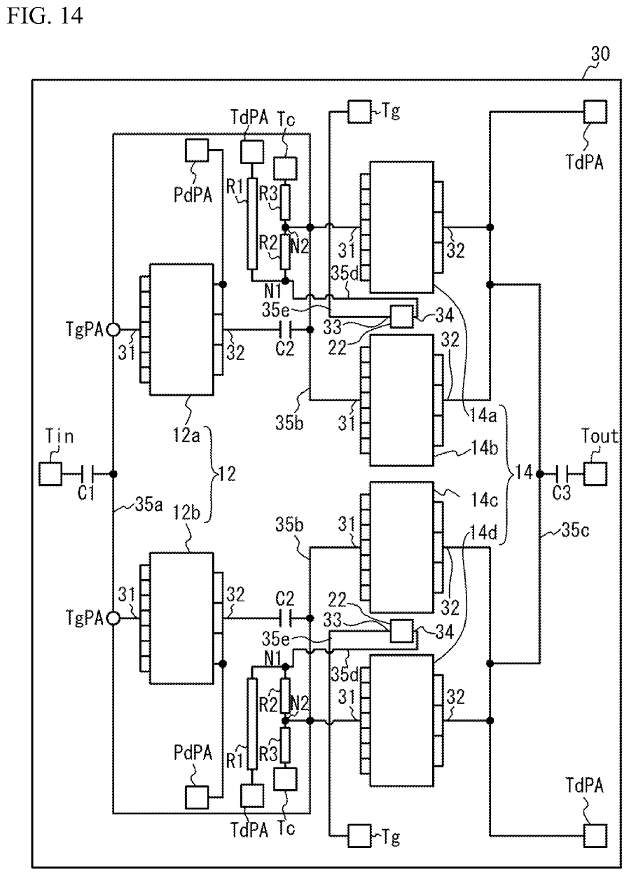

FIG. 14 is a schematic plan view of an amplifier according to a second variation of the first embodiment. As illustrated in FIG. 14, in a plan view, the wirings 35d and 35e intersect with the wirings 35b and do not intersect with the wiring 35c. The wirings 35d and 35e intersect with the wiring 35b via an insulating layer or air, for example. Other configurations are the same as those of the first embodiment, and description thereof is omitted.

Regarding the first comparative example in which the bias circuit 20 is not provided and the first and the second variations of the first embodiment, a pass characteristic S21 from the input terminal Tin to the output terminal Tout, a reflection characteristic S22 of the output terminal Tout, and a maximum available power gain (MAG) were measured. In the first variation of the first embodiment, both of the pass characteristic S21 and the MAG were reduced by about 0.7 dB in the vicinity of 19 GHz compared with the first comparative example and the second variation of the first embodiment.

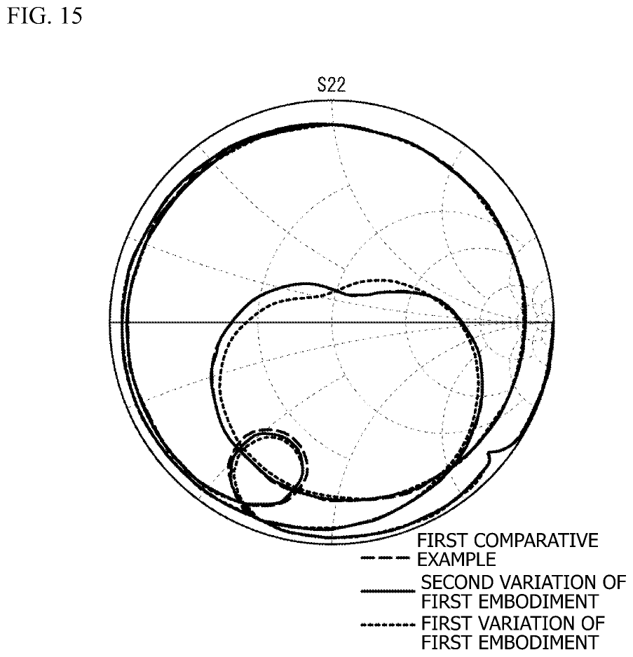

Hereinafter, the measurement result of S22 will be described. FIG. 15 is a Smith chart illustrating the reflection characteristic S22 of the first comparative example and the first and the second variations of the first embodiment. A measurement frequency ranges from 0 GHz to 40 GHz. As illustrated in FIG. 15, in the first variations of the first embodiment, the reflection characteristic S22 is shifted from that of the first comparative example. This is because in the first variation of the first embodiment, in order to arrange the transistors 22 between the transistors 14a and 14b and between the transistors 14c and 14d, the wiring 35c through which a large high-frequency power passes is made to intersect with the wirings 35d and 35e. In the second variation of the first embodiment, the wirings 35d and 35e intersect with the wirings 35b having a relatively low high-frequency power. Thus, the reflection characteristic S22 can be substantially the same as that of the first comparative example.

According to the second variation of the first embodiment, the wirings 35d and 35e of the bias circuit 20 intersect with the wirings 35b through which the signals input to the transistors 14 are transmitted, and do not intersect with the wiring 35c through which the signals output from the transistors 14 are transmitted. Thus, deterioration of the high-frequency characteristic of the amplifier circuit 10 can be suppressed.

### Third Variation of First Embodiment

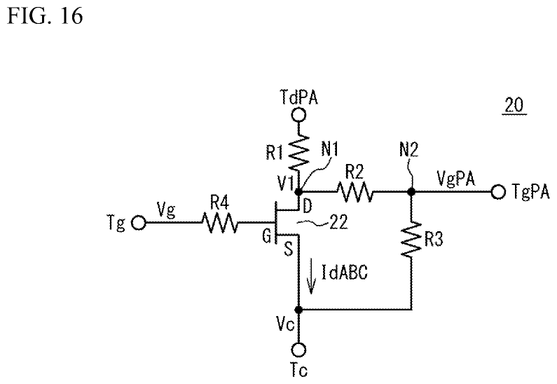

FIG. 16 is a circuit diagram of a bias circuit according to a third variation of the first embodiment. As illustrated in FIG. 16, in the third variation of the first embodiment, the source S of the transistor 22 is connected to the constant voltage terminal Tc. The constant voltage Vc is, for example, a negative voltage. Other configurations are the same as those of the first embodiment illustrated in FIG. 5 and description thereof is omitted.

In FIG. 5 of the first embodiment, when the drain bias voltage VdPA of the drain bias terminal TdPA is 24 V, the gate voltage Vg is about −2 V, for example, and the constant voltage Vc is −7 V to −20 V, for example. In FIG. 16 of the third variation of the first embodiment, when the drain bias voltage VdPA of the drain bias terminal TdPA is 24 V, the gate voltage Vg is, for example, −4 V to −2 V, and the constant voltage Vc is, for example, −4 V to −6 V.

In the bias circuit 20 illustrated in FIG. 5 of the first embodiment, the current flowing through the constant voltage terminal Tc is smaller than that of the third variation of the first embodiment. Thus, the load on the constant voltage source for supplying the constant voltage Vc is small. On the other hand, since the gate bias voltage VgPA is largely changed by the change of the drain current IdABC, when the resistance value of the resistor R1 increases, the voltage V1 decreases and the voltage applied between the source S and the drain D of the transistor 22 decreases. Thus, the temperature of the transistor 22 is lowered.

In the bias circuit 20 of the third variation of the first embodiment, by making the constant voltage Vc negative, the voltage applied between the source S and the drain D of the transistor 22 can be increased more than that of the first embodiment. Therefore, the temperature of the transistor 22 can be increased. On the other hand, since the current flowing through the constant voltage terminal Tc increases, the load on the constant voltage source that supplies the constant voltage Vc increases. The circuit configuration of the bias circuit 20 can be appropriately designed according to merits and demerits.

The embodiments disclosed herein should be considered in all respects exemplary and not restrictive. The scope of the present disclosure is not limited to the embodiment described above, is set forth by the claims and is intended to include all variations within the meaning and scope of equivalents of the claims.

### REFERENCE SIGNS LIST

10 amplifier circuit
12, 12a, 12b, 14, 14a to 14d, 22 transistor
20 bias circuit
30 semiconductor chip
31, 33 gate wiring
32, 34 drain wiring
35a to 35e wiring
40 substrate
42 buffer layer
44 electron transport layer
46 electron supply layer
48 cap layer
50 nitride semiconductor layer
52 source electrode
54 gate electrode
56 drain electrode
58 insulating film

1. An amplifier comprising:
an amplifier circuit having a characteristic changing in accordance with a thermal history; and
a bias circuit that includes an element subjected to a thermal history corresponding to the thermal history of the amplifier circuit, and supplies a bias voltage to the amplifier circuit, the bias voltage changing based on a characteristic of the element that changes in accordance with the thermal history of the element;
wherein the amplifier circuit includes a plurality of first transistors, each of the plurality of first transistors being a field effect transistor,
the element includes a second transistor that is a field effect transistor,
each of the plurality of the first transistors and the second transistor are provided on a same semiconductor chip, and
a characteristic changing in accordance with the thermal history of the amplifier circuit is a drain idle current of each of the plurality of first transistors.

2-4. (canceled)

5. The amplifier according to claim 1, wherein
each of the plurality of first transistors amplifies a high-frequency signal input to a gate and outputs the amplified high-frequency signal from a drain, and the bias circuit supplies a bias voltage to the gate of each of the plurality of first transistors.

6. The amplifier according to claim 5, wherein
a source of the second transistor is supplied with a first constant voltage,
a drain of the second transistor is connected to a node,
the bias circuit includes a resistor having one end supplied with a second constant voltage and the other end connected to the node, and
the bias voltage is a voltage corresponding to a voltage of the node.

7. The amplifier according to claim 1, wherein
a gate width of the second transistor is smaller than a gate width of each of the plurality of first transistors, and
a drain current per unit gate width of the second transistor is larger than a drain current per unit gate width of each of the plurality of first transistors.

8. The amplifier according to claim 7, wherein
a gate voltage of the second transistor is larger than a gate bias voltage of each of the plurality of first transistors.

9. The amplifier according to claim 1, wherein the second transistor is provided between the plurality of first transistors.

10. The semiconductor device according to claim 9, wherein
a wiring of the bias circuit intersects with a wiring through which signals input to the plurality of first transistors are transmitted and does not intersect with a wiring through which signals output from the plurality of first transistors are transmitted.

11. The amplifier according to claim 1, wherein
the characteristic of the amplifier circuit changes irreversibly according to the thermal history.

12. (canceled)
